(19) United States
(12) Patent Application Publication
(10) Pub. No.: US 2022/0029036 A1
(43) Pub. Date: Jan. 27, 2022

(54) CONDUCTIVE PASTE FOR SOLAR CELL ELECTRODE AND SOLAR CELL FABRICATED USING SAME

(71) Applicant: LS-NIKKO COPPER INC., Ulsan (KR)

(72) Inventors: Chung Ho KIM, Namyangju (KR); In Chul KIM, Yongin (KR); Min Soo KO, Seoul (KR); Hwa Young NOH, Hwaseong (KR); Mun Seok JANG, Seoul (KR); Kang Ju PARK, Seongnam (KR); Tae Hyun JUN, Seongnam (KR)

(21) Appl. No.: 17/298,441

(22) PCT Filed: Nov. 29, 2019
(86) PCT No.: PCT/KR2019/016809

§ 371 Date: May 28, 2021

(30) Foreign Application Priority Data
Nov. 30, 2018 (KR) 10-2018-0153124

(51) Int. Cl. H01L 31/0224; C03C 4/14; C03C 8/18; C03C 8/16

(52) U.S. Cl. CPC H01L 31/022425; C03C 4/14; C03C 2205/00; C03C 8/16; C03C 2204/00; C03C 8/18

(57) ABSTRACT

Proposed is a conductive paste for a solar cell electrode. The conductive paste includes a metal powder, a glass frit, and an organic vehicle. The glass frit includes an alkali metal oxide, and the metal powder includes an alkali component.

### TECHNICAL FIELD

The present disclosure relates generally to a conductive paste for a solar cell electrode and a solar cell fabricated using the same. More particularly, the present disclosure relates to a conductive paste with improved composition for a solar cell electrode, the conductive paste being capable of improving electrical properties when used to form a solar cell electrode, and to a solar cell fabricated using the same.

### BACKGROUND ART

Recently, as exhaustion of existing energy resources such as oil and coal has been forecasted, interest in alternative energy sources to replace the same has been increasing. Among these is a solar cell that converts solar energy into electrical energy, which is in the spotlight as a next-generation cell.

A solar cell is a semiconductor device that converts solar energy into electrical energy, and generally has a p-n junction. The basic structure of the solar cell is the same as that of a diode. A solar cell device is generally constructed using a p-type silicon semiconductor substrate 10 having a thickness of 180 to 250 μm. An n-type impurity layer having a thickness of 0.3 to 0.6 μm is formed on a light-receiving surface side of the silicon semiconductor substrate, and an anti-reflection film and a front electrode are formed thereon. Further, a back electrode is formed on a back surface of the p-type silicon semiconductor substrate.

In such a solar cell, solar cell efficiency may be determined according to the design of various layers and electrodes. In order to commercialize a solar cell, it is necessary to overcome low efficiency and low productivity, and thus a solar cell having a structure capable of maximizing the efficiency and productivity of the solar cell is required.

As an example for this, as in Patent Document 1 (Korean Patent No. 10-1575966), an insulating film includes an aluminum oxide film in order to improve passivation characteristics has been disclosed. Here, when forming a conductive paste on the insulating film and performing firing during manufacturing of a solar cell, the conductive paste has to pass through the insulating film and be connected to a conductivity type region. In the solar cell of this structure, a conventional conductive paste may not sufficiently etch an aluminum insulating film, and thus an electrode may not be stably connected to the conductivity type region. This may cause a problem that the solar cell may fail to operate or the efficiency of the solar cell may be significantly reduced.

As described above, when an additional 2 to 20 nm aluminum oxide film (AlOₓ) is formed on a front anti-reflection film of a solar cell to improve a passivation function, this provides an effect of increasing open-circuit voltage (Voc) due to the increase in hydrogenation effect and increasing short-circuit current (Isc) due to the improvement in the passivation function. However, research on a glass frit having a function capable of effectively etching such an aluminum oxide film is insufficient.

### DISCLOSURE

### Technical Problem

Accordingly, the present disclosure has been made keeping in mind the above problems occurring in the related art, and an objective of the present disclosure is to provide a conductive paste for a solar cell electrode, the conductive paste being capable of improving efficiency and characteristics of a solar cell, and provide a glass frit included therein.

However, the objectives of the present disclosure are not limited to the above-mentioned objective, and other objectives not mentioned will be clearly understood by those skilled in the art from the following description.

### Technical Solution

In order to accomplish the above objective, the present disclosure provides a conductive paste for a solar cell electrode, the conductive paste including a metal powder, a glass frit, and an organic vehicle, wherein the glass frit may include an alkali metal oxide, and the metal powder may include an alkali component.

Furthermore, the metal powder may include the alkali component in an amount of 20 to 2000 ppm with respect to the total weight of the silver powder.

Furthermore, the glass frit may be configured such that the total molar ratio of the alkali metal oxide to the entire glass frit may be 10 to 20 mol %.

Furthermore, the alkali component included in the silver powder may include at least one selected from the group consisting of lithium (Li), sodium (Na), and potassium (K).

Furthermore, the metal powder may include the alkali component in an amount of 50 to 500 ppm with respect to the total weight of the silver powder.

Furthermore, the alkali metal oxide may include at least one of lithium oxide (Li₂O), sodium oxide (Na₂O), and potassium oxide (K₂O).

Furthermore, the alkali metal oxide may be used by mixing at least two of the lithium oxide, the sodium oxide, and the potassium oxide.

The present disclosure further provides a solar cell including: a semiconductor substrate; a first conductivity type region formed on a front surface of the semiconductor substrate; a passivation film formed on the first conductivity type region and including an aluminum oxide film; a front electrode penetrating the passivation film and connected to the first conductivity type region; and a back electrode formed on a back surface of the semiconductor substrate, wherein the front electrode may be produced by applying the conductive paste and then firing the conductive paste.

### Advantageous Effects

According to the present disclosure, by allowing a glass frit to include an alkali metal oxide in a specific molar ratio, it is possible to effectively etch an aluminum oxide film and improve contact characteristics. Accordingly, it is possible to improve density and efficiency of a solar cell. Further, by controlling the amount of the composition (particularly the alkali metal oxide) in the glass frit in accordance with the thickness of the aluminum oxide film, it is possible to effectively improve the contact characteristics. However, although the aluminum oxide film (AlOₓ) can be effectively etched by controlling the amount of the alkali metal oxide (R₂O) in the glass frit, the degree of freedom for the glass frit is lowered, which limits the improvement of a fill factor.

Accordingly, by controlling the amount of an alkali component in a silver powder (Ag powder) included in the conductive paste, the present disclosure can provide an effect of increasing the degree of freedom for the glass frit, thereby achieving a high fill factor and increasing solar cell conversion efficiency. Further, by controlling the amount of the alkali component in the silver powder in accordance with the aluminum oxide film formed on an anti-reflection film, it is possible to more effectively improve the contact characteristics. That is, with a synergistic effect according to the composition of the glass frit and the composition of the silver powder, it is possible to the contact characteristics of the solar cell fabricated using these can be remarkably increased.

### DESCRIPTION OF DRAWINGS

FIG. 1 is a sectional view schematically illustrating an example of a solar cell to which a conductive paste for a solar cell electrode according to the present disclosure is applied.

### DESCRIPTION OF THE REFERENCE NUMERALS IN THE DRAWINGS

10: semiconductor substrate
20: first conductivity type region
30: anti-reflection film
32: passivation film
40: front electrode
50: second conductivity type region
60: second electrode
62: first electrode portion
64: second electrode portion

### BEST MODE

Prior to describing the present disclosure in detail below, it should be understood that the terms used herein are merely intended to describe specific embodiments and are not to be construed as limiting the scope of the present disclosure, which is defined by the appended claims. Unless otherwise defined, all terms including technical and scientific terms used herein have the same meaning as commonly understood by one of ordinary skill in the art to which this disclosure belongs.

Throughout this specification and the claims, unless otherwise defined, the terms “comprise”, “comprises”, and “comprising” will be understood to imply the inclusion of a stated object, a step or groups of objects, and steps, but not the exclusion of any other objects, steps or groups of objects or steps.

Meanwhile, unless otherwise noted, various embodiments of the present disclosure may be combined with any other embodiments. In particular, any feature which is mentioned preferably or favorably may be combined with any other features which may be mentioned preferably or favorably. Hereinafter, a description will be given of embodiments of the present disclosure and effects thereof with reference to the accompanying drawings.

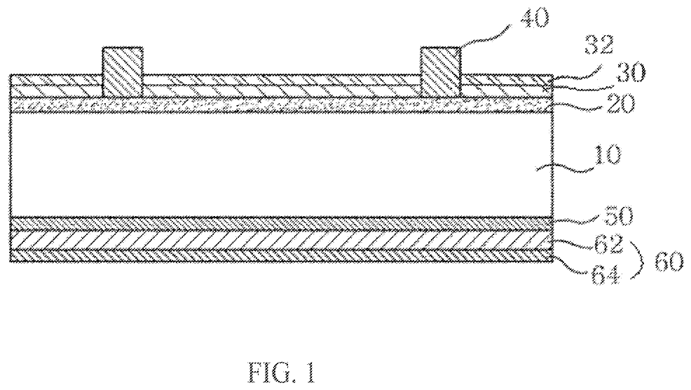

First, an example of a solar cell to which a conductive paste for a solar cell electrode according to the present disclosure is applied will be described with reference to FIG. 1, and then the conductive paste for the solar cell electrode according to the present disclosure and a glass frit and a silver powder included therein will be described in detail.

FIG. 1 is a sectional view schematically illustrating an example of a solar cell to which a conductive paste for a solar cell electrode according to the present disclosure is applied.

Referring to FIG. 1, the solar cell according to the example of the present disclosure includes a semiconductor substrate 10, a first conductivity type region 20 formed on a front surface of the semiconductor substrate 10, an anti-reflection film 30 and a passivation film 32 formed on the first conductivity type region 20, and a front electrode 40 penetrating the anti-reflection film 30 and the passivation film 32 and electrically connected to the first conductivity type region 20. Additionally, a second conductivity type region 50 formed on a back surface of the semiconductor substrate 10, and a back electrode 60 electrically connected to the second conductivity type region 50 may be included.

The semiconductor substrate 10 may be a silicon substrate (e.g., silicon wafer), may have a second conductivity type (e.g., p-type), and may have a thickness of 180 to 250 μm.

The first conductivity type region 20 may be a region having a first conductivity type (e.g., n-type) formed by doping a first conductivity type dopant on a portion of the front surface of the semiconductor substrate 10, and may have a thickness of 0.3 to 0.6 μm.

The anti-reflection film 30 located on the first conductivity type region 20 may serve to prevent light incident on the front surface of the semiconductor substrate from being reflected. Various known materials may be used as the anti-reflection film 30, for example, a silicon nitride film or the like.

The passivation film 32 located on the anti-reflection film 30 may be composed of an aluminum oxide film, and may have a thickness of 2 to 20 nm. The passivation film 32 may improve passivation characteristics by fixed charge and hydrogen passivation to improve open-circuit voltage (Voc) and short-circuit current (Isc). Although the passivation film 32 composed of an aluminum oxide film is illustrated as being located on the anti-reflection film 30, the present disclosure is not limited thereto. For example, the passivation film 32 composed of an aluminum oxide film may be formed on the first conductivity type region 20 and the anti-reflection film 30 may be located thereon.

The front electrode 40 may be formed by applying a conductive paste mixed with a metal powder, a glass frit, and an organic vehicle including a solvent and a binder on the anti-reflection film 30 and the passivation film 32, and then firing the conductive paste. Due to the fact that the conductive paste has to be connected to the first conductivity type region 20 by etching and penetrating the anti-reflection film 30 and the passivation film 32 during firing, the present disclosure employs the use of a conductive paste capable of effectively etching the passivation film 32 composed of an aluminum oxide film. The conductive paste may include a glass frit and a silver powder each having a specific composition, which will be described in more detail later.

The second conductivity type region 50 may be a back surface field (BSF) region having a second conductivity type (e.g., p-type) formed by doping a second conductivity type dopant on a portion of the back surface of the semiconductor substrate 10. The formation of the BSF region can prevent recombination of electrons and improve collection efficiency of generated carriers. The second conductivity type region 50 may be formed by various processes, for example, by a process in which substances of the back electrode 60 are diffused when at least a portion of the back electrode 60 (i.e., a first electrode portion 62) is formed.

The back electrode 60 may include aluminum and may include the first electrode portion 62 located adjacent to the second conductivity type region 50. For example, the first electrode portion 62 may be formed in such a manner that an aluminum paste composition composed of an aluminum powder, a glass frit, an organic vehicle, and additives is applied by screen printing or the like, followed by drying and then firing at a temperature of equal to or greater than 660° C. (melting point of aluminum). When firing the aluminum paste composition, aluminum may diffuse into the semiconductor substrate 10 to form the second conductivity type region 50. The back electrode 60 may further include a second electrode portion 64 formed on the first electrode portion 62 and including silver (Ag). The back electrode 60 may be formed entirely on the back surface of the semiconductor substrate 10, but the present disclosure is not limited thereto.

Hereinafter, a conductive paste for a solar cell electrode according to an embodiment of the present disclosure is provided. The conductive paste is a conductive paste that can be applied in forming an electrode of a solar cell, and can effectively etch an aluminum oxide film and achieve a high fill factor by improving series resistance of the electrode, thereby increasing solar cell conversion efficiency. For example, the conductive paste for the solar cell electrode according to the embodiment of the present disclosure may be applied in forming the front electrode 40, but the present disclosure is not limited thereto. For example, the conductive paste may be applied in forming at least a portion of the back electrode 60.

The conductive paste for the solar cell electrode according to the present disclosure may include a metal powder, a glass frit, a binder, and a solvent, which will be described in detail.

As the metal powder, a silver (Ag) powder, a gold (Au) powder, a platinum (Pt) powder, a nickel (Ni) powder, a copper (Cu) powder, or the like may be used. As the metal powder, one of the above-mentioned powders may be used alone, an alloy of the above-mentioned metals may be used, or a mixed powder of at least two of the above-mentioned powders may be used. Additionally, a metal powder obtained by performing a hydrophilic treatment or the like on the surface of the above metal powder may be used.

Of these, preferred is a silver (Ag) powder which is mainly used for the front electrode 40 due to its excellent electrical conductivity. The silver powder is preferably a pure silver powder. Alternatively, a silver-coated composite powder in which a silver layer is formed on at least a surface thereof, or an alloy including silver as a main component may be used. Further, other metal powders may be mixed and used. Examples may include aluminum, gold, palladium, copper, and nickel.

In particular, as the silver powder, a silver powder including at least one type of alkali component, so that the degree of freedom for the glass frit is increased, thereby achieving a high fill factor and increasing solar cell conversion efficiency.

The alkali component included in the silver powder includes at least one selected from the group consisting of lithium (Li), sodium (Na), and potassium (K). Preferred are Sodium (Na) and potassium (K).

It is preferable that the alkali component included in the silver powder is included in an amount of 20 to 2000 ppm with respect to the total weight of the silver powder. It is more preferable in terms of the effect of improving contact resistance that the amount of the alkali component is 80 to 500 ppm.

The alkali component may be included in the silver powder by a method including reacting a silver salt solution including silver ions and a reducing solution including a reducing agent to precipitate a silver powder, and then washing the silver powder using an alkali solution such as NaOH or KOH. Here, the amount of the alkali component in the silver powder may be controlled by controlling the concentration of the alkali solution.

The silver powder may have an average particle diameter of 0.1 to 10 μm, and preferably 0.5 to 5 μm when considering ease of pasting and density during firing, and the shape thereof may be at least one of spherical, acicular, plate-like, and amorphous. The silver powder may be used by mixing two or more powders having different average particle diameters, particle size distributions, and shapes.

The glass frit according to the present disclosure includes an alkali metal oxide, and the amount of the alkali metal oxide may be 10 to 20 mol % with respect to the entire glass frit. The glass frit including the alkali metal oxide may improve characteristics of etching an aluminum oxide film. When the above-described amount is less than 10 mol %, the characteristics of etching the aluminum oxide film may not be sufficient. On the other hand, when the above-described amount exceeds 20 mol %, the aluminum oxide film can be effectively etched, while contact characteristics with the first conductivity type region 20 may not be excellent. The amount of the alkali metal oxide is preferably 15 to 20 mol % with respect to the entire glass frit.

In an example, the alkali metal oxide may include at least one of lithium oxide (e.g., Li₂O), sodium oxide (e.g., Na₂O), and potassium oxide (e.g., K₂O). In particular, when at least two of lithium oxide, sodium oxide, and potassium oxide are used in mixture, the etching characteristics of the aluminum oxide film may be further improved.

When the glass frit includes lithium oxide, the molar ratio of lithium oxide to the entire glass frit may be 5 to 15 mol %, preferably 9 to 15 mol %. When the glass frit includes sodium oxide, the molar ratio of sodium oxide to the entire glass frit may be 1 to 5 mol %, preferably 1 to 3 mol %. When the glass frit includes potassium oxide, the molar ratio of potassium oxide to the entire glass frit may be 1 to 8 mol %, preferably 1 to 3 mol %. Within this range, the etching characteristics of the aluminum oxide film and the contact characteristics with the first conductivity type region can be effectively improved.

Here, when the glass frit includes all the lithium oxide, sodium oxide, and potassium oxide, but lithium oxide or sodium oxide is included in a higher molar ratio than potassium oxide (particularly, lithium oxide is included in a higher molar ratio than each of sodium oxide and potassium oxide), contact resistance with the first conductivity type region 20 may be further reduced.

The glass frit may include as main components (components having a molar ratio of equal to or greater than 0.5 to the entire glass frit) lead oxide (e.g., PbO), tellurium oxide (e.g., TeO₂), bismuth oxide (e.g., Bi₂O₃), and silicon oxide (e.g., SiO₂). The glass frit may further include as an additional component at least one of boron oxide, zinc oxide, aluminum oxide, titanium oxide, calcium oxide, magnesium oxide, and zirconium oxide. For example, the molar ratio of lead oxide to the entire glass frit may be 10 to 29 mol %, the molar ratio of tellurium oxide to the entire glass frit may be 20 to 38 mol %, the molar ratio of bismuth oxide to the entire glass frit may be 3 to 20 mol %, and the molar ratio of silicon oxide may be equal to or less than 20 mol %. Further, the molar ratio of each additional component to the entire glass frit may be equal to or less than 20 mol % (e.g., equal to or less than 6 mol %).

By organically combining the amount of each component, it is possible to prevent an increase in line width of the front electrode, ensuring excellent contact resistance, and ensuring excellent short-circuit current characteristics. In particular, when the amount of lead oxide is too high, there may be a problem in that it may be difficult to ensure eco-friendliness, and viscosity may become too low during melting and thus the line width of the front electrode may increase during firing. Therefore, it is preferable that lead oxide is include within the above range in the glass frit. Further, for example, when the alkali metal oxide is included in the glass frit in the above-described range, when a large amount of alkaline earth metal oxide (i.e., calcium oxide, magnesium oxide, or the like) is included, contact resistance may increase. Accordingly, the glass frit may include the alkali metal oxide at a higher molar ratio than the alkaline earth metal oxide, and for example, the glass frit may not include the alkaline earth metal oxide.

In the above-described description, it has been illustrated that the glass frit is a leaded glass frit so that the anti-reflection film 30 and the passivation film 32 can be etched stably during firing of the conductive paste. With a synergistic effect according to the composition of the glass frit and the composition of the silver powder, contact characteristics of the solar cell fabricated using these can be remarkably increased.

The average particle diameter of the glass frit is not limited, but may fall within the range of 0.5 to 10 μm, and the glass frit may be used by mixing different types of particles having different average particle diameters. Preferably, at least one type of glass frit has an average particle diameter (D50) of equal to or greater than 3 μm and equal to or less than 5 μm. This makes it possible to ensure excellent reactivity during firing, and in particular, minimize damage to an n-layer at a high temperature, improve adhesion, and ensure excellent open-circuit voltage (Voc). It is also possible to reduce an increase in the line width of the electrode during firing.

Further, the glass transition temperature (Tg) of the glass frit may be, but not limited to, 200 to 600° C. Preferably, the glass transition temperature falls within the range of equal to or greater than 200° C. and less than 300° C. With the use of the glass frit having a low glass transition temperature of less than 300° C., melting uniformity can be increased, and uniform characteristics of the solar cell can be ensured. Additionally, excellent contact characteristics can be ensured even during low temperature/quick firing, and optimization for high surface resistance (90 to 120 Ω/sq) solar cells.

Crystallization characteristics of the glass frit can be regarded as an important factor. In a conventional glass frit, when performing a differential scanning calorimetry (DSC) measurement, the first crystallization generally occurs at a temperature of equal to or greater than 550° C. However, in the present disclosure, the initial crystallization peak occurs at a temperature of less than 400° C. on DSC measurement data of the glass frit, whereby crystallization occurs more quickly during firing. This significantly reduces an increase in the line width of the electrode during firing, thereby making it possible to improve electrical characteristics. Preferably, on the DSC data, the first crystallization peak occurs at a temperature of less than 400° C., and the second crystallization peak occurs at a temperature of equal to or greater than 400° C. and equal to or less than 500° C. More preferably, all crystallization peaks occur at a temperature of less than 400° C. on the DSC data.

The organic vehicle including the organic binder and the solvent is required to have characteristics such as maintaining a uniform mixture of the metal powder, the glass frit, and the like. For example, when the conductive paste is applied to the substrate by screen printing, there is a need for characteristics that make the conductive paste homogeneous to suppress blurring and flow of a printed pattern, and also improve dischargeability and plate separation characteristics of the conductive paste from a screen plate.

Examples of the organic binder may include a cellulose ester compound such as cellulose acetate, cellulose acetate butyrate, and the like; a cellulose ether compound such as ethyl cellulose, methyl cellulose, hydroxypropyl cellulose, hydroxyethyl cellulose, hydroxypropyl methyl cellulose, hydroxyethyl methyl cellulose, and the like; an acrylic compound such as polyacrylamide, polymethacrylate, polymethyl methacrylate, polyethyl methacrylate, and the like; and a vinyl compound such as polyvinyl butyral, polyvinyl acetate, polyvinyl alcohol, and the like. At least one of the binders may be selected and used.

The solvent may be used by selecting at least one of compounds selected from the group consisting of dimethyl adipate, diethylene glycol butyl ether acetate, texanol, dioctyl phthalate, dibutyl phthalate, diethyleneglycol, ethylene glycol buthyl ether, ethylene glycol butyl ether acetate, diethylene glycol butyl ether, and the like. Preferred are dimethyl adipate and diethylene glycol butyl ether acetate.

The conductive paste according to the present disclosure may further include, as needed, other additives generally known, for example, dispersants, leveling agents, plasticizers, viscosity modifiers, surfactants, oxidizing agents, metal oxides, metal organic compounds, waxes, and the like.

The metal powder may be included in an amount of 40 to 98 parts by weight (e.g., 60 to 95 parts by weight) with respect to 100 parts by weight of the entire conductive paste in consideration of electrode thickness formed during printing and linear resistance of the electrode. When the amount of the metal powder is less than 40 parts by weight (e.g., 60 parts by weight), resistivity of a formed electrode may be high. On the other hand, when the amount thereof exceeds 98 parts by weight (e.g., 95 parts by weight), there is a problem in that the metal powder may not be uniformly dispersed due to an insufficient amount of other components.

The glass frit may be included in an amount of 1 to 15 parts by weight with respect to 100 parts by weight of the entire conductive paste. When the amount of the glass frit is less than 1 part by weight, there is a possibility that electrical resistivity may increase due to incomplete firing. On the other hand, when the amount thereof is greater than 15 parts by weight, there is a possibility that electrical resistivity may increase due to too many glass components in a fired body of the silver powder. The organic binder is not limited, but may be included in an amount of 1 to 15 parts by weight with respect to 100 parts by weight of the entire conductive paste. When the amount of the organic binder is less than 1 part by weight, viscosity of the composition and adhesive force of a formed electrode pattern may decrease. On the other hand, when the amount of thereof exceeds 15 parts by weight, the amount of the metal powder, solvent, dispersant, and the like may not be sufficient.

The solvent may be included in an amount of 5 to 25 parts by weight with respect to 100 parts by weight of the entire conductive paste. When the amount of the solvent is less than 5 parts by weight, the metal powder, glass frit, organic binder, and the like may not be uniformly mixed. On the other hand, when the amount thereof exceeds 25 parts by weight, the amount of the metal powder may be reduced and electrical conductivity of the produced front electrode 40 may be reduced thereby. The other additives may be included in an amount of 0.1 to 5 parts by weight with respect to 100 parts by weight of the entire conductive paste.

The above-described conductive paste for the solar cell electrode may be prepared in such a manner that the metal powder, glass frit, organic binder, solvent, and additives are mixed and dispersed, followed by filtering and degassing.

The present disclosure also provides a method of forming a solar cell electrode, characterized in that the conductive paste is coated on a substrate, dried, and fired, and provides a solar cell electrode produced by the method. In the method of forming the solar cell electrode according to the present disclosure, except for the use of the conductive paste including the glass frit of the above characteristics, the substrate, printing, drying, and firing can be implemented by using methods generally used in manufacturing of solar cells.

In an example, the substrate may be a silicon wafer, and the electrode produced from the paste according to the present disclosure may be a finger electrode or a busbar electrode of the front electrode 40. The electrode may be printed on the passivation film 32 including the aluminum oxide film and then penetrate the passivation film 32 including the aluminum oxide film (more particularly, the passivation film 32 including the aluminum oxide film and the anti-reflection film 30) by fire-through during firing to be connected (e.g., electrically connected) to the first conductivity type region 20. The printing may be screen printing or offset printing, the drying may be performed at to 250° C., and the firing may be performed at 600 to 950° C. Preferably, the firing is performed at 800 to 950° C., more preferably, high temperature/high speed firing is performed at 850 to 900° C. for 5 seconds to 1 minute, and the printing is performed to a thickness of 20 to 60 μm. However, the present disclosure is not limited to this, and printing methods, drying and firing process conditions, and the like may be variously modified.

According to the present disclosure, by allowing the glass frit to include the alkali metal oxide in a specific molar ratio and allowing the silver powder to include the alkali component in a specific amount, it is possible to effectively etch the aluminum oxide film and to improve the contact characteristics. Accordingly, it is possible to improve density and efficiency of a solar cell. Further, by controlling the amount of the composition (particularly the alkali metal oxide) in the glass frit and the amount of the alkali component in the silver powder in accordance with the thickness of the aluminum oxide film, it is possible to effectively improve the contact characteristics.

### Example and Comparative Example

A silver powder, a glass frit, an organic binder, a solvent, additives, and the like were added and dispersed using a three-roll mill, and then a silver powder was mixed and dispersed using the three-roll mill. Here, an ethyl cellulose resin was used as the organic binder, and diethylene glycol butyl ether acetate was used as the solvent, and the silver powder had a spherical shape and had an average particle diameter of 1 μm. The composition of a conductive paste during mixing is as illustrated in Table 1 below, the composition of the glass frit used at this time is as illustrated in Table 2, and the composition of the alkali component amount in the silver powder is as illustrated in Table 3. Finally, degassing under reduced pressure was performed to prepare a conductive paste. The configurations of Examples and Comparative Examples of the conductive paste are illustrated in Tables 4 to 6.

TABLE 1

| | Example and |
|---|---|
| Classification [% by weight] | Comparative Example |
| Ethyl cellulose resin | 0.45 |
| Diethylene glycol butyl ether acetate | 6.3 |
| Wax | 0.28 |
| Silver powder | 88.5 |
| Glass frit | 3.1 |
| Dispersant (ED121) | 0.45 |
| Additive (polydimethylsiloxane oil) | 0.92 |

TABLE 2

| Classification | Glass | Glass | Glass |
|---|---|---|---|
| [mol %] | frit A | frit B | frit C |
| PbO | 25 | 25 | 25 |
| TeO₂ | 34 | 34 | 34 |
| Bi₂O₃ | 15 | 15 | 5 |
| SiO₂ | 5 | 5 | 7 |
| Li₂O | 7 | 13 | 8 |
| Na₂O | 5 | 2 | 1 |
| K₂O | 5 | 2 | 6 |
| B₂O₃ | — | — | — |
| ZnO | 2 | 2 | 6 |
| Al₂O₃ | 2 | 2 | 5 |
| TiO₂ | — | — | 3 |
| CaO | — | — | — |
| ZrO₂ | — | — | 1 |
| Total | 100.0 | 100.0 | 100.0 |
| Total molar ratio | 17.0 | 17.0 | 15.0 |
| of alkali metal | | | |
| oxides to the | | | |
| entire glass frit | | | |

TABLE 3

| Classification [ppm] | Na | K |
|---|---|---|
| Silver powder A | 1337 | — |
| Silver powder B | 447 | — |
| Silver powder C | 235 | — |
| Silver powder D | 48 | — |
| Silver powder E | 23 | — |
| Silver powder F | — | 423 |
| Silver powder G | — | 52 |
| Silver powder H | — | 27 |
| Silver powder I | 223 | 237 |
| Silver powder J | 47 | 38 |
| Silver powder K | — | — |

TABLE 4

| Classification [ppm] | Silver powder | Glass frit |
|---|---|---|
| Example 1 | Silver powder A | Glass frit A |
| Example 2 | Silver powder B | Glass frit A |
| Example 3 | Silver powder C | Glass frit A |
| Example 4 | Silver powder D | Glass frit A |
| Example 5 | Silver powder E | Glass frit A |
| Example 6 | Silver powder F | Glass frit A |
| Example 7 | Silver powder G | Glass frit A |
| Example 8 | Silver powder H | Glass frit A |
| Example 9 | Silver powder I | Glass frit A |
| Example 10 | Silver powder J | Glass frit A |
| Comparative Example 1 | Silver powder K | Glass frit A |

TABLE 5

| Classification [ppm] | Silver powder | Glass frit |
|---|---|---|
| Example 11 | Silver powder A | Glass frit B |
| Example 12 | Silver powder B | Glass frit B |
| Example 13 | Silver powder C | Glass frit B |
| Example 14 | Silver powder D | Glass frit B |
| Example 15 | Silver powder E | Glass frit B |
| Example 16 | Silver powder F | Glass frit B |
| Example 17 | Silver powder G | Glass frit B |
| Example 18 | Silver powder H | Glass frit B |
| Example 19 | Silver powder I | Glass frit B |
| Example 20 | Silver powder J | Glass frit B |
| Comparative Example 2 | Silver powder K | Glass frit B |

TABLE 6

| Classification [ppm] | Silver powder | Glass frit |
|---|---|---|
| Example 21 | Silver powder A | Glass frit C |
| Example 22 | Silver powder B | Glass frit C |
| Example 23 | Silver powder C | Glass frit C |
| Example 24 | Silver powder D | Glass frit C |
| Example 25 | Silver powder E | Glass frit C |
| Example 26 | Silver powder F | Glass frit C |
| Example 27 | Silver powder G | Glass frit C |
| Example 28 | Silver powder H | Glass frit C |
| Example 29 | Silver powder I | Glass frit C |
| Example 30 | Silver powder J | Glass frit C |
| Comparative Example 3 | Silver powder K | Glass frit C |

### Experimental Example

An n-type dopant was diffused on a front surface of a silicon wafer to form a first conductivity type region, and an anti-reflection film composed of a silicon nitride film and a passivation film composed of an aluminum oxide film were formed on the first conductivity type region. A conductive paste prepared according to each of the above Examples and Comparative Examples was pattern-printed on the silicon nitride film and the aluminum oxide film by screen printing using a 35 μm mesh, and dried at 200 to 350° C. for to 30 seconds using a belt-type drying furnace. Thereafter, an aluminum paste was printed on a back surface of the silicon wafer, and then dried in the same manner as above. Finally, firing was performed at a temperature of 500 to 900° C. for 20 to 30 seconds using a belt-type firing furnace, thereby fabricating a solar cell.

The fabricated solar cell was evaluated for etching characteristics of the aluminum oxide film from an electro luminescence image, and contact resistance was measured using a contact resistance meter. Here, when a front electrode formed by firing the conductive paste penetrates the aluminum oxide film and is connected to the first conductivity type region, the etching characteristics of the aluminum oxide film were determined to be good, and when the front electrode cannot penetrate the aluminum oxide film and thus cannot be connected to the first conductivity type region, the etching characteristics of the aluminum oxide film were determined to be poor. Further, contact resistance is a contact resistance measured using the contact resistance meter when sheet resistance of a semiconductor substrate is 100 ohms and current density (Jsc) is 30 mA/cm². The results are illustrated in Table 7.

TABLE 7

| | Contact |
|---|---|
| Classification | resistance[ohm · cm²] |
| Example 1 | 28.3 |
| Example 2 | 19.2 |
| Example 3 | 19.7 |
| Example 4 | 20.7 |
| Example 5 | 20.9 |
| Example 6 | 19.4 |
| Example 7 | 20.5 |
| Example 8 | 21.1 |
| Example 9 | 19.9 |
| Example 10 | 20.1 |
| Comparative Example 1 | 21.4 |
| Example 11 | 31.3 |
| Example 12 | 18.7 |
| Example 13 | 18.9 |
| Example 14 | 20.3 |
| Example 15 | 20.8 |
| Example 16 | 19.2 |
| Example 17 | 20.1 |
| Example 18 | 21.1 |
| Example 19 | 19.3 |
| Example 20 | 19.9 |
| Comparative Example 2 | 20.9 |
| Example 21 | 28.8 |
| Example 22 | 19.4 |
| Example 23 | 19.7 |
| Example 24 | 21.3 |
| Example 25 | 21.3 |
| Example 26 | 19.7 |
| Example 27 | 21.0 |
| Example 28 | 21.8 |
| Example 29 | 20.9 |
| Example 30 | 21.5 |
| Comparative Example 3 | 22.1 |

Referring to Table 7, it can be seen that each solar cell according to each Example has improved contact resistance compared to that of each Comparative Example. More preferably, it can be seen that when silver powders B, C, F, I, and J are used, the contact resistance is lowest, indicating that alkali component amount in the silver powder is preferably 50 to 500 ppm. In the case of using glass frit B, it can be seen that the contact resistance is lower than that of the other Examples using the same silver powder, indicating that the amount of lithium oxide among alkali metal oxides in the glass frit is preferably 9 to 15 mol %. In addition, cells fabricated using conductive pastes prepared according to Example 12 and Comparative Example 2, which have the lowest contact resistance, were measured for short-circuit current (Isc), open-circuit voltage (Voc), solar cell conversion efficiency (Eff), fill factor (FF), resistance (Rser, Rsht), and line width using solar cell efficiency measurement equipment (cetisPV-Celltest 3, produced by Halm), and the results are illustrated in Table 8 below.

TABLE 8

| | IV DATA | | | | | | | |
|---|---|---|---|---|---|---|---|---|
| | | | | | | | Grid | Grid |
| | Isc | Voc | Eff | FF | Rser | Rsht | resistance | resistance |
| | (A) | (V) | (%) | (%) | (Ω) | (Ω) | (1-2) | (2-3) |
| Example 12 | 9.723 | 0.6421 | 20.53 | 79.76 | 0.00096 | 331.5 | 29.3 | 28.9 |
| Comparative | 9.724 | 0.6422 | 20.44 | 79.33 | 0.00110 | 592.0 | 31.0 | 30.4 |
| Example 2 | | | | | | | | |

As illustrated in Table 8, it can be seen that when a silver powder including a specific amount of an alkali component and a glass frit including a specific molar ratio of an alkali metal oxide are used together, the contact characteristics are improved, resulting that a high fill factor (FF) is achieved and the solar cell conversion efficiency (Eff) is increased.

The features, structures, and effects illustrated in individual exemplary embodiments as above can be combined or modified with other exemplary embodiments by those skilled in the art. Therefore, content related to such combinations or modifications should be understood to fall within the scope of the present disclosure.

1. A conductive paste for a solar cell electrode, the conductive paste comprising
a metal powder,
a glass frit, and
an organic vehicle,
wherein the glass frit comprises an alkali metal oxide, and
the metal powder comprises an alkali component.

2. The conductive paste of claim 1, wherein the metal powder comprises the alkali component in an amount of 20 to 2000 ppm with respect to the total weight of the silver powder.

3. The conductive paste of claim 1, wherein the glass frit is configured such that the total molar ratio of the alkali metal oxide to the entire glass frit is 10 to 20 mol %.

4. The conductive paste of claim 1, wherein the alkali component included in the silver powder comprises at least one selected from the group consisting of lithium (Li), sodium (Na), and potassium (K).

5. The conductive paste of claim 1, wherein the metal powder comprises the alkali component in an amount of 50 to 500 ppm with respect to the total weight of the silver powder.

6. The conductive paste of claim 1, wherein the alkali metal oxide comprises at least one of lithium oxide (Li₂O), sodium oxide (Na₂O), and potassium oxide (K₂O).

7. The conductive paste of claim 6, wherein the alkali metal oxide is used by mixing at least two of the lithium oxide, the sodium oxide, and the potassium oxide.

8. A solar cell comprising:
a semiconductor substrate;
a first conductivity type region formed on a front surface of the semiconductor substrate;
a passivation film formed on the first conductivity type region and including an aluminum oxide film;
a front electrode penetrating the passivation film and connected to the first conductivity type region; and
a back electrode formed on a back surface of the semiconductor substrate,
wherein the front electrode is produced by applying the conductive paste of claim 1, and then firing the conductive paste.
